(19) United States
(12) Patent Application Publication
(10) Pub. No.: US 2025/0350274 A1
(43) Pub. Date: Nov. 13, 2025

(54) Electronic circuit having a floating gate structure

(71) Applicant: InnoLux Corporation, Miao-Li County (TW)

(72) Inventors: Ming-Chun TSENG, Miao-Li County (TW); Kung-Chen KUO, Miao-Li County (TW); Po-Syun CHEN, Miao-Li County (TW)

(73) Assignee: InnoLux Corporation, Miao-Li County (TW)

(21) Appl. No.: 19/173,840

(22) Filed: Apr. 9, 2025

Related U.S. Application Data
(60) Provisional application No. 63/644,525, filed on May 9, 2024.

(30) Foreign Application Priority Data
Oct. 25, 2024 (CN) 202411497982.X

(51) Int. Cl. H03K 17/14

(52) U.S. Cl. CPC H03K 17/145

(57) ABSTRACT

An electronic circuit has an output circuit and a first switching transistor. The output circuit has at least one first output transistor. The at least one first output transistor has a control end, a first end, and a second end. The first switching transistor has a control end, a first end, and a second end. The at least one first output transistor and the first switching transistor are complementary transistors. The first end of the first switching transistor is coupled to the control end of the at least one first output transistor. During a specific duration, the first switching transistor is turned off, while the control end of the at least one first output transistor is in a floating state.

### CROSS REFERENCE TO RELATED APPLICATION

This application claims the benefit of U.S. Provisional Application No. 63/644,525, filed on May 9, 2024. The content of the application is incorporated herein by reference.

### BACKGROUND OF THE DISCLOSURE

### 1. Field of the Disclosure

The disclosure relates to an electronic circuit, and more particularly to an electronic circuit having a floating gate structure.

### 2. Description of the Prior Art

When designing electronic circuits, several key factors must be considered: leakage current, voltage stress on transistors, and transistor switching speed. Leakage current affects power consumption and circuit stability. Even when a transistor is turned off, small leakage currents can lead to energy loss, especially in low-power applications. Designers must select transistors with low leakage currents to improve circuit efficiency and reliability. Additionally, transistors operating under high voltage experience greater stress, impacting their reliability and lifespan. Furthermore, transistor switching speed determines their efficiency in switching operations. Faster switching speeds reduce switching losses and improve overall efficiency. This is particularly critical for high-frequency applications such as switching power supplies and high-speed data transmission circuits.

### SUMMARY OF THE DISCLOSURE

In accordance with some embodiments, the present disclosure provides an electronic circuit comprising an output circuit and a first switch transistor. The output circuit comprises at least one first output transistor, and the at least one first output transistor comprises a control end, a first end, and a second end. The first switch transistor comprises a control end, a first end, and a second end. The at least one first output transistor and the first switch transistor are complementary transistors. The first end of the first switch transistor is coupled to the control end of the at least one first output transistor. During a specific duration, the first switch transistor is turned off, and the control end of the at least one first output transistor is in a floating state.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a circuit diagram of an electronic circuit according to one embodiment of the disclosure.

FIG. 2 is a signal timing diagram of the electronic circuit in FIG. 1.

FIG. 3 is a circuit diagram of an electronic circuit according to another embodiment of the disclosure.

FIG. 4 is a signal timing diagram of the electronic circuit in FIG. 3.

FIG. 5 to FIG. 9 are circuit diagrams of electronic circuits according to different embodiments of the disclosure.

FIG. 10 is a schematic diagram of an electronic circuit according to one embodiment of the disclosure connected to a next-stage circuit.

### DETAILED DESCRIPTION

By referring to the detailed description below in conjunction with the accompanying drawings, the disclosure can be understood. It should be noted that for ease of understanding and simplicity of the drawings, multiple figures in the disclosure only depict parts of the electronic device, and specific components in the drawings are not drawn to actual proportions.

Additionally, the quantities and sizes of components in the figures are merely illustrative and are not intended to limit the scope of the disclosure. Throughout the specification and claims of the disclosure, certain terms are used to refer to specific components. Those skilled in the art should understand that manufacturers of electronic devices might refer to the same components by different names.

This document is not intended to distinguish components that have the same function but are named differently. In the specification and claims of the disclosure, the terms “including,” “comprising,” “having,” and the like are open-ended terms, and thus are to be interpreted as “including but not limited to.” Therefore, when terms such as “including,” “comprising,” and/or “having” are used in the description of the disclosure, they specify the presence of corresponding features, regions, steps, operations, and/or components, but do not exclude the presence of one or more corresponding features, regions, steps, operations, and/or components.

Directional terms mentioned herein, such as “up,” “down,” “front,” “back,” “left,” “right,” etc., are merely references to the directions in the figures. Therefore, the directional terms are used for explanation and are not intended to limit the disclosure.

In the drawings, each figure illustrates general features of methods, structures, and/or materials used in specific embodiments. However, these figures should not be construed as defining or limiting the scope or nature of the embodiments covered by the disclosure. For example, for clarity, the relative sizes, thicknesses, and positions of various layers, regions, and/or structures may be reduced or enlarged.

Additionally, when a component is referred to as being “on another component,” there is a vertical relationship between the two, and the component can be above or below the other component, depending on the orientation of the device. Additionally, when a component is referred to as being “on another component,” there is a vertical relationship between the two, and the component can be above or below the other component, depending on the orientation of the device.

It should be understood that when a component or film layer is referred to as being “connected to” another component or film layer, it can be directly connected to the other component or film layer, or there may be intervening components or film layers between them. When a component is referred to as being “directly connected to” another component or film layer, there are no intervening components or film layers between them. Additionally, when a component is referred to as being “coupled to another component (or its variant),” it can be directly electrically connected to the other component, or indirectly connected (e.g., indirectly electrically connected) to the other component through one or more components.

In the disclosure, when a component “disconnects” another component, electrical signals cannot flow between the two components during the specified time.

The term “approximately” or “about” is generally interpreted as being within ±10% of the given value, or within ±5%, ±3%, ±2%, ±1%, or ±0.5% of the given value.

In the specification and claims, ordinal numbers such as “first,” “second,” etc., are used to modify components. They do not imply any prior numbering of the components, nor do they imply an order between components or in a manufacturing method. The use of ordinal numbers is solely to distinguish one component with a certain name from another component with the same name. The claims and the specification may not use the same terminology. Accordingly, the first component in the specification may be the second component in the claims.

It should be understood that the following examples can be combined, reorganized, or mixed with features of different embodiments without departing from the spirit of the disclosure to create other embodiments. Features from various embodiments can be freely combined as long as they do not contradict or conflict with the spirit of the invention.

In the disclosure, the electronic device may include a display device, a lighting device, an antenna device, a sensing device, a medical device, a splicing device, or any combination thereof, but not limited to these. The display device can be a non-self-luminous display or a self-luminous display as needed and can be a color display or a monochrome display as needed. The antenna device can be a liquid crystal type antenna device or a non-liquid crystal type antenna device; the sensing device can be a device for sensing capacitance, light, heat, or ultrasound; the medical device can be a medical testing device; and the splicing device can be a display splicing device or an antenna splicing device, but not limited to these. The electronic device may include electronic components, which may include passive components and active components, such as capacitors, resistors, inductors, diodes, electrowetting elements, transistors, dies, or chips. The diode can be a die or a chip and may include a light-emitting diode (LED), a photodiode, or a varactor, but is not limited to this. The light-emitting diode may include, for example, an organic light-emitting diode (OLED), a mini-LED, a micro-LED, or a quantum dot LED, but is not limited to this. Electrowetting elements may include, for example, a digital microfluidic (DMF) platform, an electrowetting display, or an electrowetting-on-dielectric application on a lab-on-chip, but are not limited to this. Transistors may include, for example, top-gate thin-film transistors, bottom-gate thin-film transistors, or dual-gate thin-film transistors, but are not limited to this. The electronic device may also include, as needed, fluorescent materials, phosphor materials, quantum dot (QD) materials, or other suitable materials, but is not limited to these. The electronic device may have peripheral systems such as a drive system, control system, light source system, etc., to support the devices and components within the electronic device.

It should be noted that the technical features described in the different embodiments below can be replaced, reorganized, or combined with each other to form another embodiment without departing from the spirit of the disclosure.

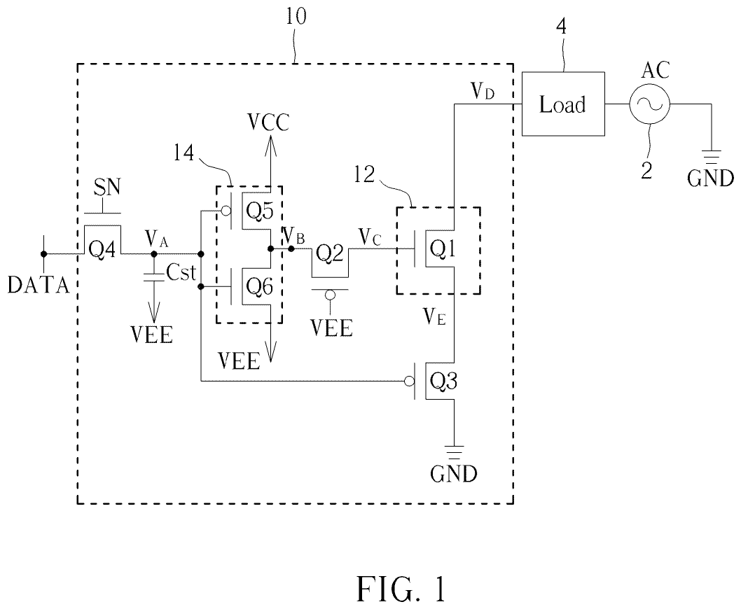

Please refer to FIG. 1. FIG. 1 is a circuit diagram of an electronic circuit 10 according to one embodiment of the disclosure. The electronic circuit 10 is coupled to a load 4 and an alternating-current (AC) power source 2. The AC power source 2 provides an alternating-current (AC) signal AC. The load 4 may be, for example, a conductive fluid or another liquid in a pixel of an electrowetting display (EWD), or a sample or detection liquid in a medical testing device, but the disclosure is not limited thereto. The electronic circuit 10 comprises an output circuit 12, a first switch transistor Q2, a first transistor Q3, a data switch Q4, a storage capacitor Cst, and a first inverter 14. The output circuit 12 comprises a first output transistor Q1. In the embodiment, the first output transistor Q1 is an N-type metal-oxide-semiconductor field-effect transistor (NMOSFET), and the first switch transistor Q2 and the first transistor Q3 are P-type metal-oxide-semiconductor field-effect t transistors (PMOSFETs). Thus, the first output transistor Q1 and the first switch transistor Q2 are complementary transistors, and the first output transistor Q1 and the first transistor Q3 are complementary transistors. The first end of the first output transistor Q1 is coupled to the load 4, the second end of the first output transistor Q1 is coupled to the first end of the first transistor Q3, and the control end of the first output transistor Q1 is coupled to the first end of the first switch transistor Q2. The second end of the first switch transistor Q2 is coupled to the output of the first inverter 14, and the control end of the first switch transistor Q2 receives the system voltage VEE. The system voltage VEE may be, for example, a negative voltage or zero volts. The second end of the first transistor Q3 is coupled to the ground end GND, and the control end of the first transistor Q3 is coupled to the input of the first inverter 14. The voltage at the ground end GND is zero volts. In the embodiment, the data switch Q4 is an N-type metal-oxide-semiconductor field-effect transistor, but the disclosure is not limited thereto. In other embodiments, the data switch Q4 may be a P-type metal-oxide-semiconductor field-effect transistor. The first end of the data switch Q4 receives the data voltage DATA, the second end of the data switch Q4 is coupled to the first end of the storage capacitor Cst, the control end of the data switch Q4 receives the control signal SN, and the second end of the storage capacitor Cst receives the system voltage VEE. The input of the first inverter 14 is coupled to the first end of the storage capacitor Cst, and the output of the first inverter 14 is coupled to the second end of the first switch transistor Q2. The first inverter 14 comprises a transistor Q5 and a transistor Q6. The transistor Q5 is a P-type metal-oxide-semiconductor field-effect transistor, and the transistor Q6 is an N-type metal-oxide-semiconductor field-effect transistor. The first end of the transistor Q5 receives the system voltage VCC, the second end of the transistor Q5 is coupled to the output of the first inverter 14, and the control end of the transistor Q5 is coupled to the input of the first inverter 14. The system voltage VCC may be, for example, positive 6 volts and is higher than the system voltage VEE. Additionally, the first end of the transistor Q6 is coupled to the output of the first inverter 14, the second end of the transistor Q6 receives the system voltage VEE, and the control end of the transistor Q6 is coupled to the input of the first inverter 14.

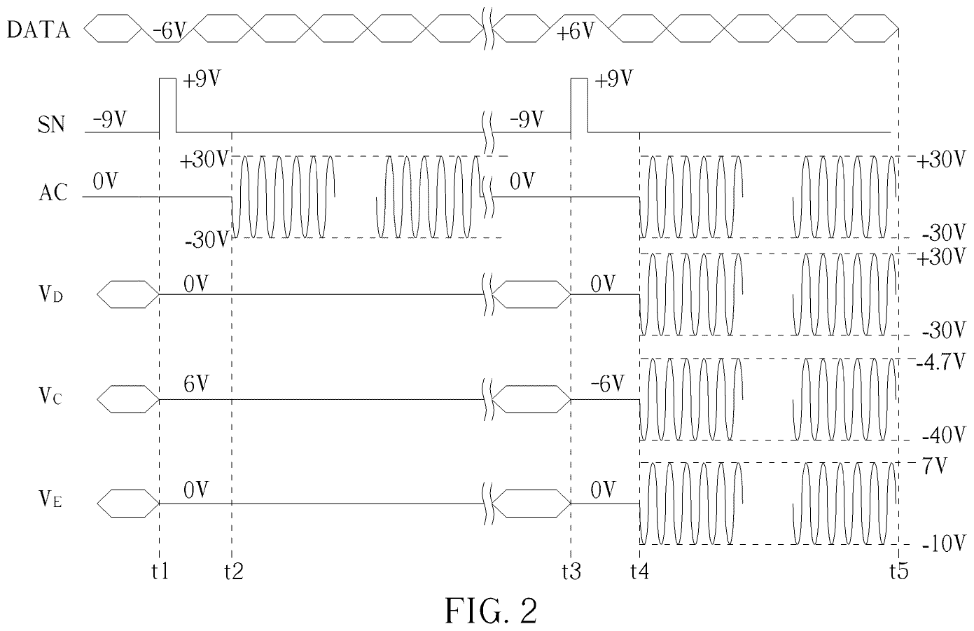

Please refer to FIG. 1 and FIG. 2. FIG. 2 is a signal timing diagram of the electronic circuit 10 in FIG. 1. At time t1, the control signal SN rises from −9 volts to +9 volts, and the data voltage DATA is −6 volts. This causes the data switch Q4 to turn on, resulting in the voltage V_{A} at the first end of the storage capacitor Cst being −6 volts. Consequently, the first transistor Q3 turns on, making the voltage V_{E} at the first end of the first transistor Q3 equal to the ground voltage (i.e., 0 volts). Because the voltage V_{A} is −6 volts, the transistor Q5 turns on while the transistor Q6 turns off, making the voltage V_{B} at the output of the first inverter 14 equal to the system voltage VCC of +6 volts. Because the system voltage VEE is 0 volts or a negative voltage, the first switch transistor Q2 turns on at time t1, causing the voltage V_{C} at the first end of the first switch transistor Q2 to equal the voltage V_{B} of +6 volts, thereby turning on the first output transistor Q1. Since both the first output transistor Q1 and the first transistor Q3 are on, the voltage V_{D} at the first end of the first output transistor Q1 equals the voltage V_{E} of 0 volts.

At time t2, the AC power source 2 begins to provide an alternating-current signal AC with a voltage range from −30 volts to +30 volts. At this time, because both the first output transistor Q1 and the first transistor Q3 are conducting, the voltages V_{D} and V_{E} remain unaffected by the alternating-current signal AC and stay at 0 volts.

At time t3, the control signal SN rises from −9 volts to +9 volts, and the data voltage DATA is +6 volts. This causes the data switch Q4 to turn on, resulting in the voltage V_{A} at the first end of the storage capacitor Cst being +6 volts, and turning off the first transistor Q3. Because the voltage V_{A} is +6 volts, the transistor Q5 turns off while the transistor Q6 turns on, making the voltage V_{B} at the output of the first inverter 14 equal to the system voltage VEE. In the embodiment, the system voltage VEE is −6 volts, causing the first switch transistor Q2 to turn on at time t3, making the voltage V_{C} equal to the voltage V_{B} at −6 volts, and turning off the first output transistor Q1.

At time t4, the AC power source 2 starts providing the alternating-current signal AC again. During the specific duration from time t4 to time t5, as the voltage of the alternating-current signal AC oscillates between −30 volts and +30 volts, once the voltage of the alternating-current signal AC is less than the system voltage VEE minus the threshold voltage of the first switch transistor Q2 (i.e., VEE−VTHQ2), the first switch transistor Q2 will be turned off. Here, VTHQ2 is the threshold voltage of the first switch transistor Q2. During the period when the alternating-current signal AC oscillates between −30 volts and +30 volts, once the first switch transistor Q2 is turned off, even if the voltage of the alternating-current signal AC subsequently rises above (VEE−VTHQ2), the first switch transistor Q2 will remain off. Therefore, during the specific duration from time t4 to time t5, once the voltage of the alternating-current signal AC is less than (VEE−VTHQ2), the first switch transistor Q2 will remain off. Additionally, due to the parasitic capacitance of the first output transistor Q1, the voltages V_{C} and V_{E} will oscillate with the alternating-current signal AC. As shown in FIG. 2, during the specific duration from time t4 to time t5, the voltage V_{C} oscillates between −4.7 volts and −40 volts, while the voltage V_{E} oscillates between −7 volts and −10 volts. Since the first switch transistor Q2 remains off during the specific duration from time t4 to time t5, and the voltage V_{C} oscillates with the alternating-current signal AC, the control end of the first output transistor Q1 is floating during the specific duration from time t4 to time t5. In other words, the voltage V_{C} changes with the voltage V_{D}. Furthermore, during the specific duration from time t4 to time t5, because the voltage V_{E} oscillates between +7 volts and −10 volts, the voltage difference between the first and second ends of the first transistor Q3 and the voltage difference between the control end and the second end of the first transistor Q3 will not be too large, thereby relatively reducing the voltage stress on the first output transistor Q1 and the first transistor Q3, and consequently reducing the leakage current of the first output transistor Q1 and the first transistor Q3. Moreover, the oscillation of the voltage V_{E} is not affected by the parasitic capacitance of the first output transistor Q1, so the electronic circuit 10 may use a larger first output transistor Q1. Additionally, with the reduced impact of the parasitic capacitance of the first output transistor Q1, the response speed of the first output transistor Q1 is improved, allowing the AC power source 2 to use a higher frequency alternating-current signal AC.

In another embodiment of the disclosure, the electronic circuit 10 may further comprise a detection circuit for detecting the voltage V_{D}.

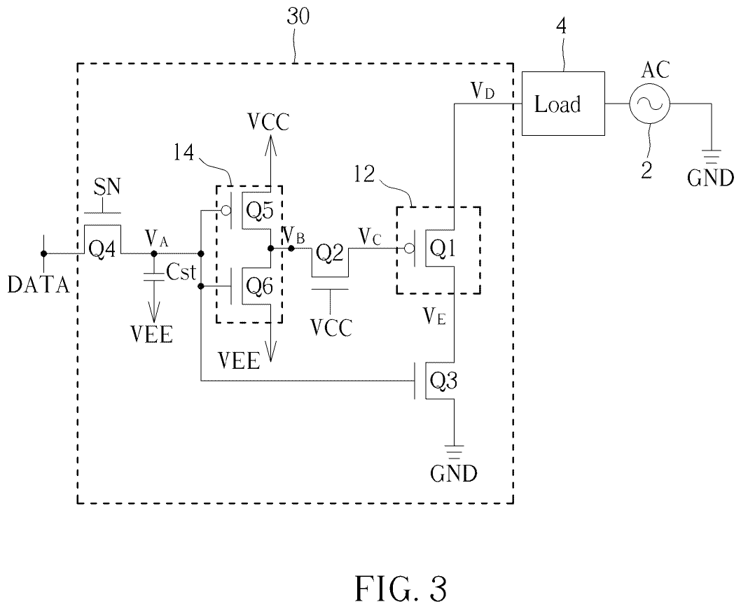

Please refer to FIG. 3. FIG. 3 is a circuit diagram of an electronic circuit 30 according to another embodiment of the disclosure. The electronic circuit 30 is coupled to a load 4 and an AC power source 2. The electronic circuit 30 is similar to the electronic circuit 10, with the main difference being the types of the first output transistor Q1, the first switch transistor Q2, and the first transistor Q3 in the electronic circuit 30 compared to those in the electronic circuit 10. The first output transistor Q1 in the electronic circuit 30 is a P-type metal-oxide-semiconductor field-effect transistor (PMOSFET), while the first switch transistor Q2 and the first transistor Q3 are N-type metal-oxide-semiconductor field-effect transistors (NMOSFETs). Additionally, the control end of the first switch transistor Q2 receives the system voltage VCC. Furthermore, the coupling method between the components of the electronic circuit 30 is the same as that of the electronic circuit 10, which will not be reiterated herein.

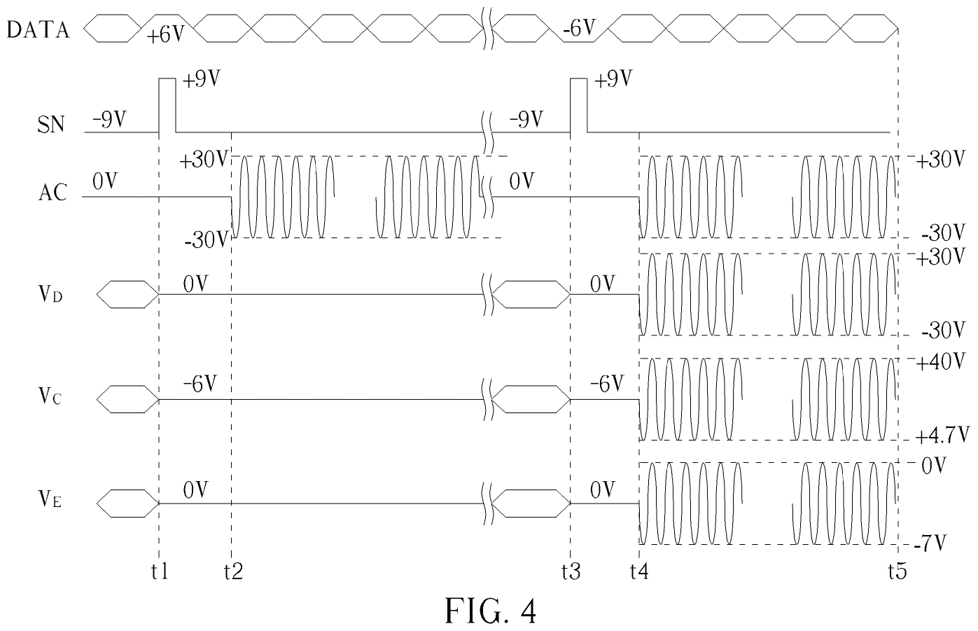

Please refer to FIG. 3 and FIG. 4. FIG. 4 is a signal timing diagram of the electronic circuit 30 in FIG. 3. At time t1, the control signal SN rises from −9 volts to +9 volts, and the data voltage DATA is +6 volts. This causes the data switch Q4 to turn on, resulting in the voltage V_{A} at the first end of the storage capacitor Cst being +6 volts, and turning on the first transistor Q3, which makes the voltage V_{E} at the first end of the first transistor Q3 equal to the ground voltage (i.e., 0 volts). Because the voltage V_{A} is +6 volts, the transistor Q5 turns off while the transistor Q6 turns on, making the voltage V_{B} at the output of the first inverter 14 equal to the system voltage VEE of −6 volts. Since the system voltage VCC is +6 volts, the first switch transistor Q2 turns on at time t1, causing the voltage V_{C} at the first end of the first switch transistor Q2 to equal the voltage V_{B} of −6 volts, thereby turning on the first output transistor Q1. With both the first output transistor Q1 and the first transistor Q3 on, the voltage V_{D} at the first end of the first output transistor Q1 equals the voltage V_{E} of 0 volts.

At time t2, the AC power source 2 starts providing the alternating-current signal AC, and the voltage range of the alternating-current signal AC is from −30 volts to +30 volts. At this time, because both the first output transistor Q1 and the first transistor Q3 are conducting, the voltages V_{D} and V_{E} are unaffected by the alternating-current signal AC and remain at 0 volts.

At time t3, the control signal SN rises from −9 volts to +9 volts, and the data voltage DATA is −6 volts. This causes the data switch Q4 to turn on, resulting in the voltage V_{A} at the first end of the storage capacitor Cst being −6 volts, and turning off the first transistor Q3. Because the voltage V_{A} is −6 volts, the transistor Q5 turns on while the transistor Q6 turns off, making the voltage V_{B} at the output of the first inverter 14 equal to the system voltage VCC. Since the system voltage VCC is +6 volts, the first switch transistor Q2 turns on at time t3, causing the voltage V_{C} to equal the voltage V_{B} of +6 volts, and turning off the first output transistor Q1.

At time t4, the AC power source 2 starts providing the alternating-current signal AC again. During the specific duration from time t4 to time t5, as the voltage of the alternating-current signal AC oscillates between −30 volts and +30 volts, once the voltage V_{C} is greater than the system voltage VCC minus the threshold voltage of the first switch transistor Q2 (i.e., VCC−VTHQ2), the first switch transistor Q2 is turned off. Here, VTHQ2 is the threshold voltage of the first switch transistor Q2. During the period when the alternating-current signal AC oscillates between −30 volts and +30 volts, once the first switch transistor Q2 is turned off, even if the voltage V_{C} subsequently decreases below (VCC−VTHQ2), the first switch transistor Q2 will remain off. Therefore, during the specific duration from time t4 to time t5, once the voltage V_{C} is greater than (VCC−VTHQ2), the first switch transistor Q2 will remain off. Additionally, due to the parasitic capacitance of the first output transistor Q1, the voltages V_{C} and V_{E} will oscillate with the alternating-current signal AC. As shown in FIG. 4, during the specific duration from time t4 to time t5, the voltage V_{C} oscillates between +4.7 volts and +40 volts, while the voltage V_{E} oscillates between −7 volts and 0 volts. Since the first switch transistor Q2 remains off during the specific duration from time t4 to time t5, and the voltage V_{C} oscillates with the alternating-current signal AC, the control end of the first output transistor Q1 is floating during the specific duration from time t4 to time t5. Additionally, during the specific duration from time t4 to time t5, because the voltage V_{E} oscillates between −7 volts and 0 volts, the voltage difference between the first and second ends of the first transistor Q3 and the voltage difference between the control end and the second end of the first transistor Q3 will not be too large, thereby relatively reducing the voltage stress on the first output transistor Q1 and the first transistor Q3, and consequently reducing the leakage current of the first output transistor Q1 and the first transistor Q3. Moreover, the oscillation of the voltage V_{E} is not affected by the parasitic capacitance of the first output transistor Q1, so the electronic circuit 10 may use a larger first output transistor Q1. Additionally, with the reduced impact of the parasitic capacitance of the first output transistor Q1, the response speed of the first output transistor Q1 is improved, allowing the AC power source 2 to use a higher frequency alternating-current signal AC.

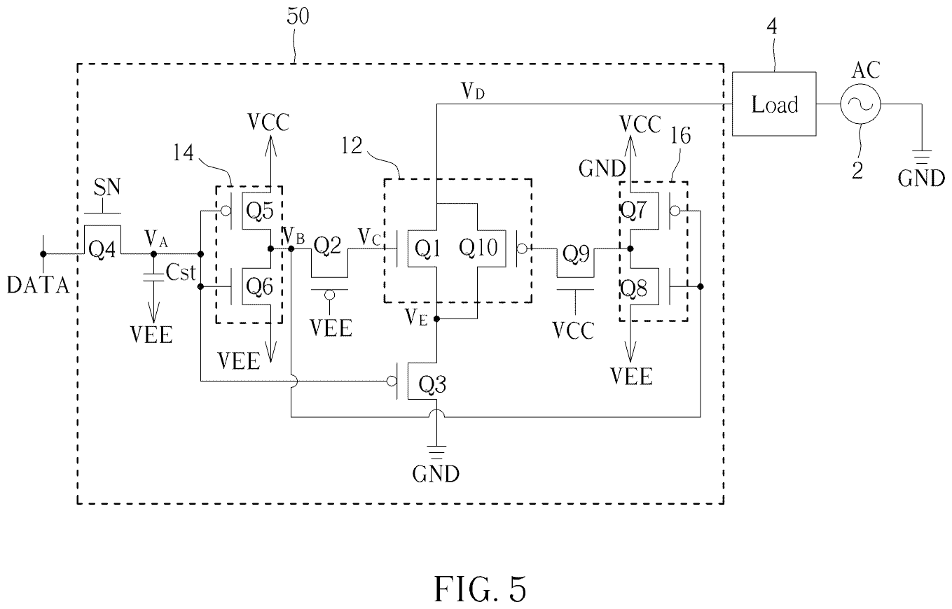

Please refer to FIG. 5. FIG. 5 is a circuit diagram of an electronic circuit 50 according to another embodiment of the disclosure. The electronic circuit 50 comprises all the components of the electronic circuit 10 in FIG. 1, plus a second inverter 16 and a second switch transistor Q9, and the output circuit 12 of the electronic circuit 50 further comprises a second output transistor Q10. The input of the second inverter 16 is coupled to the output of the first inverter 14, the output of the second inverter 16 is coupled to the second end of the second switch transistor Q9, the first end of the second switch transistor Q9 is coupled to the control end of the second output transistor Q10, and the first end of the second output transistor Q10 is coupled to the first end of the first output transistor Q1. The second inverter 16 comprises transistors Q7 and Q8, where the transistor Q7 and the second output transistor Q10 are P-type metal-oxide-semiconductor field-effect transistors (PMOSFETs), and the first output transistor Q1 and the transistor Q8 are N-type metal-oxide-semiconductor field-effect transistors (NMOSFETs). Therefore, the second output transistor Q10 and the first output transistor Q1 are complementary transistors, and the second output transistor Q10 is also a complementary transistor to the second switch transistor Q9. The first end of the transistor Q7 receives the system voltage VCC, the second end of the transistor Q7 is coupled to the output of the second inverter 16, and the control end of the transistor Q7 is coupled to the input of the second inverter 16. Additionally, the first end of the transistor Q8 is coupled to the output of the second inverter 16, the second end of the transistor Q8 receives the system voltage VEE, and the control end of the transistor Q8 is coupled to the input of the second inverter 16. In the embodiment, the operation of the first inverter 14, the first switch transistor Q2, and the first output transistor Q1 of the electronic circuit 50 is consistent with the operation of the first inverter 14, the first switch transistor Q2, and the first output transistor Q1 in FIG. 1, and the operation of the second inverter 16, the second switch transistor Q9, and the second output transistor Q10 of the electronic circuit 50 is consistent with the operation of the first inverter 14, the first switch transistor Q2, and the first output transistor Q1 in FIG. 3, and will not be reiterated herein. For example, during the specific duration from time t4 to time t5, the second switch transistor Q9 is off, and the control end of the second output transistor Q10 is floating. The use of transistors Q7, 08, the second switch transistor Q9, and the second output transistor Q10 provides an additional signal transmission path, enhancing the current driving capability of the electronic circuit 50 and improving signal transmission performance.

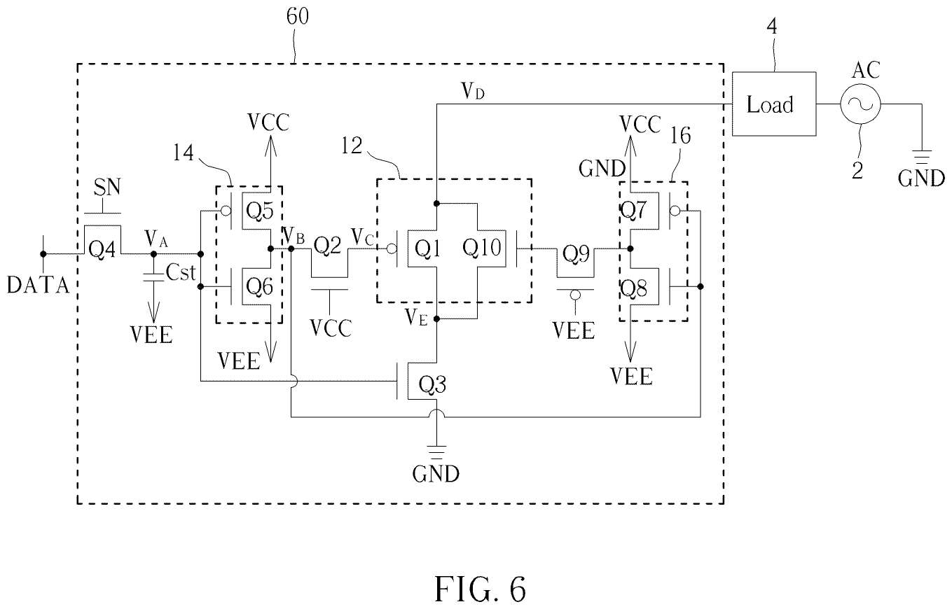

Please refer to FIG. 6. FIG. 6 is a circuit diagram of an electronic circuit 60 according to another embodiment of the disclosure. The electronic circuit 60 comprises all the components of the electronic circuit 30 in FIG. 3, plus a second inverter 16 and a second switch transistor Q9, and the output circuit 12 of the electronic circuit 50 further comprises a second output transistor Q10. The input of the second inverter 16 is coupled to the output of the first inverter 14, the output of the second inverter 16 is coupled to the second end of the second switch transistor Q9, the first end of the second switch transistor Q9 is coupled to the control end of the second output transistor Q10, and the first end of the second output transistor Q10 is coupled to the first end of the first output transistor Q1. The second inverter 16 comprises transistors Q7 and Q8.

The electronic circuit 60 is similar to the electronic circuit 50, with the main difference being the types of the first output transistor Q1, the first switch transistor Q2, the first transistor Q3, the second output transistor Q10, and the second switch transistor Q9 in the electronic circuit 60 compared to those in the electronic circuit 50. The first output transistor Q1 and the second switch transistor Q9 in the electronic circuit 60 are P-type metal-oxide-semiconductor field-effect transistors (PMOSFETS), while the first switch transistor Q2, the first transistor Q3, and the second output transistor Q10 in the electronic circuit 60 are N-type metal-oxide-semiconductor field-effect transistors (NMOSFETs). In the embodiment, the operation of the first inverter 14, the first switch transistor Q2, and the first output transistor Q1 in the electronic circuit 60 is consistent with the operation of the first inverter 14, the first switch transistor Q2, and the first output transistor Q1 in FIG. 3, and the operation of the second inverter 16, the second switch transistor Q9, and the second output transistor Q10 in the electronic circuit 60 is consistent with the operation of the first inverter 14, the first switch transistor Q2, and the first output transistor Q1 in FIG. 1, and will not be reiterated herein. For example, during the specific duration from time t4 to time t5, the second switch transistor Q9 is off, and the control end of the second output transistor Q10 is floating. The use of transistors Q7, 08, the second switch transistor Q9, and the second output transistor Q10 provides an additional signal transmission path, enhancing the current driving capability of the electronic circuit 50 and improving signal transmission performance.

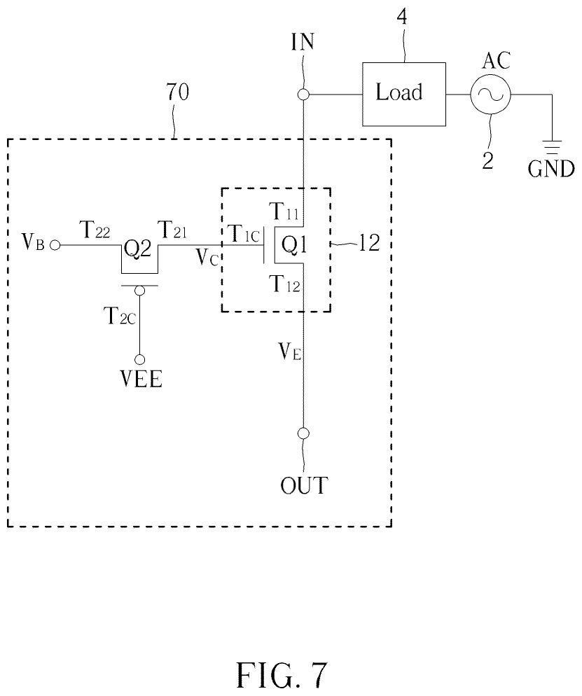

According to another embodiment, the disclosed electronic circuit may comprise an output circuit 12 and a first switch transistor Q2. Please refer to FIG. 7, which is a circuit diagram of an electronic circuit 70 according to another embodiment of the disclosure. The electronic circuit 70 may be coupled to a load 4 and an AC power source 2. The electronic circuit 70 comprises an output circuit 12 and a first switch transistor Q2. The output circuit 12 comprises a first output transistor Q1. The first end T₁₁ of the first output transistor Q1 serves as the input IN of the electronic circuit 70 and is coupled to the load 4. The second end T₁₂ of the first output transistor Q1 serves as the output OUT of the electronic circuit 70 to output the voltage VE, and the control end T_{1C} of the first output transistor Q1 is coupled to the first end T₂₁ of the first switch transistor Q2. The second end T₂₂ of the first switch transistor Q2 receives the voltage V_{B}, and the control end T_{2C} of the first switch transistor Q2 receives the system voltage VEE. In the embodiment, the first output transistor Q1 is an N-type metal-oxide-semiconductor field-effect transistor (NMOSFET), while the first switch transistor Q2 is a P-type metal-oxide-semiconductor field-effect transistor (PMOSFET). Therefore, the first output transistor Q1 and the first switch transistor Q2 are complementary transistors.

In another embodiment, the first output transistor Q1 in FIG. 7 is a P-type metal-oxide-semiconductor field-effect transistor, the first switch transistor Q2 is an N-type metal-oxide-semiconductor field-effect transistor, and the control end T_{2C} of the first switch transistor Q2 receives the system voltage VCC.

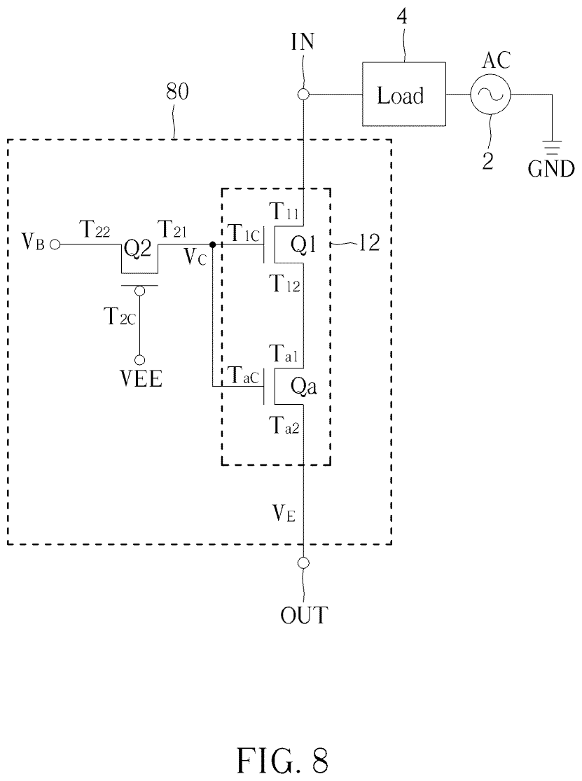

Please refer to FIG. 8. FIG. 8 is a circuit diagram of an electronic circuit 80 according to another embodiment of the disclosure. The electronic circuit 80 comprises an output circuit 12 and a first switch transistor Q2. The output circuit 12 comprises two first output transistors Q1 and Qa. The first end T₁₁ of the first output transistor Q1 serves as the input IN of the electronic circuit 70 and is coupled to the load 4. The second end T₁₂ of the first output transistor Q1 is coupled to the first end Tₐ₁ of the first output transistor Qa. The second end Tₐ₂ of the first output transistor Qa serves as the output OUT of the electronic circuit 80 to output the voltage VE, and the control end T_{1C} of the first output transistor Q1 and the control end T_{aC} of the first output transistor Qa are both coupled to the first end T₂₁ of the first switch transistor Q2. The second end T₂₂ of the first switch transistor Q2 receives the voltage V_{B}, and the control end T_{2C} of the first switch transistor Q2 receives the system voltage VEE. In the embodiment, both first output transistors Q1 and Qa are N-type metal-oxide-semiconductor field-effect transistors (NMOSFETS), while the first switch transistor Q2 is a P-type metal-oxide-semiconductor field-effect transistor (PMOSFET). Therefore, the first output transistor Qa and the first switch transistor Q2 are complementary transistors.

In another embodiment, both first output transistors Q1 and Qa in FIG. 8 are P-type metal-oxide-semiconductor field-effect transistors, the first switch transistor Q2 is an N-type metal-oxide-semiconductor field-effect transistor, and the control end T_{2C} of the first switch transistor Q2 receives the system voltage VCC.

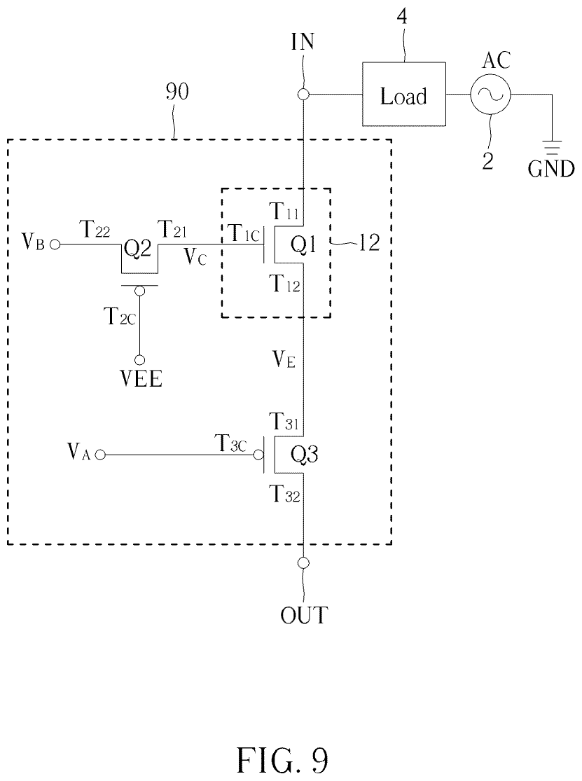

According to another embodiment, the disclosed electronic circuit may comprise an output circuit 12, a first switch transistor Q2, and a first transistor Q3. Please refer to FIG. 9. FIG. 9 is a circuit diagram of an electronic circuit 90 according to another embodiment of the disclosure. The electronic circuit 90 may be coupled to a load 4 and an AC power source 2. The electronic circuit 90 comprises an output circuit 12, a first switch transistor Q2, and a first transistor Q3. The output circuit 12 comprises a first output transistor Q1. The first end T₁₁ of the first output transistor Q1 serves as the input IN of the electronic circuit 90 and is coupled to the load 4. The second end T₁₂ of the first output transistor Q1 is coupled to the first end T31 of the first transistor Q3, and the control end T_{1C} of the first output transistor Q1 is coupled to the first end T₂₁ of the first switch transistor Q2. The second end T₂₂ of the first switch transistor Q2 receives the voltage V_{B}, and the control end T_{2C} of the first switch transistor Q2 receives the system voltage VEE. The second end T32 of the first transistor Q3 serves as the output OUT of the electronic circuit 90, and the control end T3C of the first transistor Q3 receives the voltage V_{A}. In the embodiment, the first output transistor Q1 is an N-type metal-oxide-semiconductor field-effect transistor (NMOSFET), while the first switch transistor Q2 and the first transistor Q3 are P-type metal-oxide-semiconductor field-effect transistors (PMOSFETs). Therefore, the first output transistor Q1 and the first switch transistor Q2 are complementary transistors, and the first output transistor Q1 and the first transistor Q3 are complementary transistors.

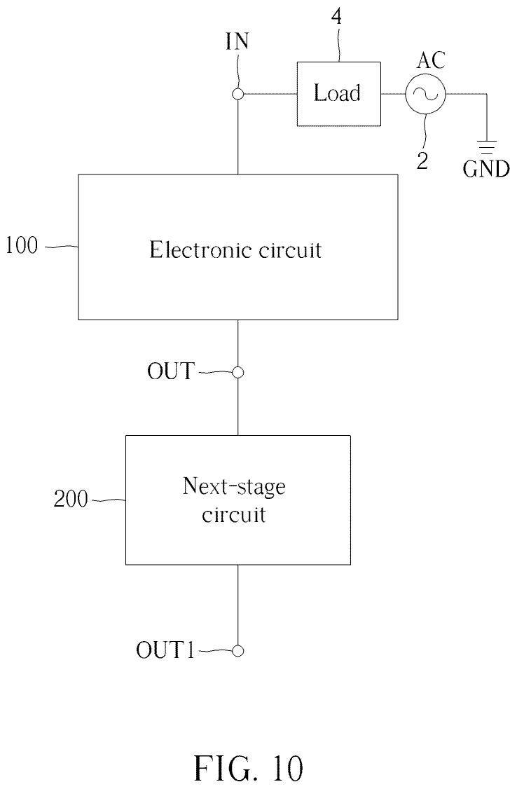

Please refer to FIG. 10. FIG. 10 is a schematic diagram of an electronic circuit 100 in one embodiment of the disclosure connected to a next-stage circuit 200. The electronic circuit 100 can be any of the electronic circuits 10, 30, 50, 60, 70, 80, or 90 from the above embodiments, where the input IN of the electronic circuit 100 is the first end of the first output transistor Q1. The output OUT of the electronic circuit 100 may be the second end of the first output transistor Q1 or Qa (as shown in FIG. 7 and FIG. 8), or the second end of the first transistor Q3 (as shown in FIGS. 1, 3, 5, 6, and 9). The next-stage circuit 200 may comprise conductors, resistors, transistors, and/or switch elements and may comprise another output OUT1.

The control end of the first output transistor Q1 in the electronic circuit of the above embodiments of the disclosure is floating at a specific duration, which may relatively reduce the voltage stress on the first output transistor Q1, thereby reducing the leakage current of the first output transistor Q1. Furthermore, the oscillation of the voltage V_{E} is not affected by the parasitic capacitance of the first output transistor Q1, so the electronic circuit may use a larger first output transistor Q1. Additionally, since the impact of the parasitic capacitance of the first output transistor Q1 is reduced, the response speed of the first output transistor Q1 is improved, allowing the AC power source 2 to use a higher frequency AC signal.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic circuit, comprising:
an output circuit comprising at least one first output transistor, the at least one first output transistor comprising a control end, a first end, and a second end; and
a first switch transistor comprising a control end, a first end, and a second end, wherein the at least one first output transistor and the first switch transistor are complementary transistors;
wherein the first end of the first switch transistor is coupled to the control end of the at least one first output transistor; and
wherein during a specific duration, the first switch transistor is turned off, and the control end of the at least one first output transistor is in a floating state.

2. The electronic circuit of claim 1, further comprising a first transistor, wherein the first transistor and the at least one first output transistor are complementary transistors.

3. The electronic circuit of claim 2, wherein a first end of the first transistor is coupled to the second end of the at least one first output transistor.

4. The electronic circuit of claim 2, further comprising a data switch and a storage capacitor, wherein a first end of the data switch receives a data voltage, and a second end of the data switch is coupled to a first end of the storage capacitor and a control end of the first transistor.

5. The electronic circuit of claim 4, further comprising a first inverter, wherein an input of the first inverter is coupled to the first end of the storage capacitor, and an output of the first inverter is coupled to the second end of the first switch transistor.

6. The electronic circuit of claim 5, further comprising a second inverter and a second switch transistor, and the output circuit further comprising at least one second output transistor, wherein an input of the second inverter is coupled to the output of the first inverter, an output of the second inverter is coupled to a second end of the second switch transistor, a first end of the second switch transistor is coupled to a control end of the at least one second output transistor, and a first end of the at least one second output transistor is coupled to the first end of the at least one first output transistor.

7. The electronic circuit of claim 1, further comprising another first output transistor, wherein the another first output transistor and the first switch transistor are complementary transistors.

8. The electronic circuit of claim 1, wherein the second end of the at least one first output transistor is electrically connected to a next-stage circuit, and the next-stage circuit comprises a conductor, a resistor, a transistor, and/or a switch element.

9. The electronic circuit of claim 1, wherein during the specific duration, a voltage at the control end of the at least one first output transistor changes with a voltage at the first end of the at least one first output transistor.

10. The electronic circuit of claim 1, further comprising a data switch and a storage capacitor, wherein a first end of the data switch receives a data voltage, and a second end of the data switch is coupled to a first end of the storage capacitor.

11. The electronic circuit of claim 10, further comprising a first inverter, wherein an input of the first inverter is coupled to the first end of the storage capacitor, and an output of the first inverter is coupled to the second end of the first switch transistor.

12. The electronic circuit of claim 11, further comprising a second inverter and a second switch transistor, and the output circuit further comprising at least one second output transistor, wherein an input of the second inverter is coupled to the output of the first inverter, an output of the second inverter is coupled to a second end of the second switch transistor, a first end of the second switch transistor is coupled to a control end of the at least one second output transistor, and a first end of the at least one second output transistor is coupled to the first end of the at least one first output transistor.

13. The electronic circuit of claim 12, wherein during the specific duration, the second switch transistor is turned off, and the control end of the at least one second output transistor is in a floating state.

14. The electronic circuit of claim 12, wherein the at least one second output transistor and the at least one first output transistor are complementary transistors.

15. The electronic circuit of claim 7, further comprising a first transistor, wherein a control end of the first transistor is coupled to the first end of the storage capacitor, and a first end of the first transistor is coupled to the second end of the at least one first output transistor.

16. The electronic circuit of claim 15, wherein the first transistor and the at least one first output transistor are complementary transistors.

17. The electronic circuit of claim 15, further comprising a first inverter, wherein an input of the first inverter is coupled to the first end of the storage capacitor, and an output of the first inverter is coupled to the second end of the first switch transistor.

18. The electronic circuit of claim 17, further comprising a second inverter and a second switch transistor, and the output circuit further comprising at least one second output transistor, wherein an input of the second inverter is coupled to the output of the first inverter, an output of the second inverter is coupled to a second end of the second switch transistor, a first end of the second switch transistor is coupled to a control end of the at least one second output transistor, and a first end of the at least one second output transistor is coupled to the first end of the at least one first output transistor.

19. The electronic circuit of claim 18, wherein during the specific duration, the second switch transistor is turned off, and the control end of the at least one second output transistor is in a floating state.

20. The electronic circuit of claim 18, wherein the at least one second output transistor and the at least one first output transistor are complementary transistors.
